(19) United States
(12) Patent Application Publication
(10) Pub. No.: US 2026/0082716 A1
(43) Pub. Date: Mar. 19, 2026

(54) IMAGE SENSING DEVICE

(71) Applicant: SK hynix Inc., Icheon-si (KR)

(72) Inventor: Dong Ho HA, Icheon-si (KR)

(21) Appl. No.: 19/276,417

(22) Filed: Jul. 22, 2025

(30) Foreign Application Priority Data
Sep. 13, 2024 (KR) 10-2024-0125851

(51) Int. Cl. H10F 39/00

(52) U.S. Cl. CPC H10F 39/807; H10F 39/802

(57) ABSTRACT

Image sensing devices are disclosed. In an embodiment, an image sensing device includes a substrate including a first surface and a second surface facing or opposite to the first surface; a plurality of photoelectric conversion regions arranged adjacent to each other within the substrate and configured to convert incident light received through the first surface into photocharges; a pixel isolation structure configured to isolate adjacent photoelectric conversion regions of the photoelectric conversion regions from each other within the substrate; a floating diffusion region disposed between the plurality of photoelectric conversion regions and in contact with the second surface of the substrate; and a plurality of transfer gates disposed on side surfaces of the plurality of photoelectric conversion regions so as not to vertically overlap the plurality of photoelectric conversion regions.

### CROSS-REFERENCE TO RELATED APPLICATION

This patent document claims the priority and benefits of Korean patent application No. 10-2024-0125851, filed on Sep. 13, 2024, which is incorporated by reference in its entirety as part of the disclosure of this patent document.

### TECHNICAL FIELD

The technology and implementations disclosed in this patent document generally relate to an image sensing device.

### BACKGROUND

An image sensor is a device that captures optical images by converting light into electrical signals using a photosensitive semiconductor material that reacts to light. With the recent advancements in the automotive, medical, computer and communication industries, the demand for high-performance image sensors is growing across various fields, such as smartphones, digital cameras, camcorders, personal communication systems (PCSs), game consoles, IoT (Internet of Things), robots, surveillance cameras, medical micro cameras, etc.

### SUMMARY

Various embodiments of the disclosed technology relate to an image sensing device designed to improve its operational characteristics.

In an embodiment of the disclosed technology, an image sensing device may include a substrate including a first surface and a second surface facing or opposite to the first surface; a plurality of photoelectric conversion regions arranged adjacent to each other within the substrate and configured to convert incident light received through the first surface into photocharges; a pixel isolation structure disposed between adjacent photoelectric conversion regions of the plurality of photoelectric conversion regions within the substrate to isolate the adjacent photoelectric conversion regions from each other within the substrate; a floating diffusion region disposed between the plurality of photoelectric conversion regions and in contact with the second surface of the substrate; and a plurality of transfer gates disposed on side surfaces of the plurality of photoelectric conversion regions so as not to vertically overlap the plurality of photoelectric conversion regions.

In another embodiment of the disclosed technology, an image sensing device may include a substrate including a first surface and a second surface facing or opposite to the first surface; a photoelectric conversion region disposed in the substrate and in contact with the second surface of the substrate, and configured to generate photocharges by converting incident light received through the first surface of the substrate; a floating diffusion region spaced apart from the photoelectric conversion region and in contact with the second surface of the substrate; and a plurality of transfer gates disposed on side surfaces of the photoelectric conversion region so as not to vertically overlap the photoelectric conversion region.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on an embodiment of the disclosed technology.

FIG. 2 is a plan view illustrating an example of a planar structure of one pixel block in a pixel array shown in FIG. 1 based on an embodiment of the disclosed technology.

FIG. 3 is a cross-sectional view illustrating a cross-section of the pixel block taken along the line A-A′ shown in FIG. 2 based on an embodiment of the disclosed technology.

FIG. 4 is a cross-sectional view illustrating a cross-section of the pixel block taken along the line B-B′ shown in FIG. 2 based on an embodiment of the disclosed technology.

FIG. 5 is a cross-sectional view illustrating a cross-section of the pixel block taken along the line C-C′ shown in FIG. 2 based on an embodiment of the disclosed technology.

FIG. 6 is a cross-sectional view illustrating a cross-section of the pixel block taken along the line D-D′ shown in FIG. 2 based on an embodiment of the disclosed technology.

FIG. 7 is a plan view illustrating an example of a planar structure of a unit pixel when the pixel array of FIG. 1 includes a plurality of unit pixels arranged in a Bayer pattern based on an embodiment of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. The disclosed technology can be implemented in some embodiments to provide an imagen sensing device that can improve its operational characteristics. The disclosed technology can be implemented in some embodiments to provide an image sensing device that can enhance the transmission characteristics of photocharges while increasing its well capacity.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

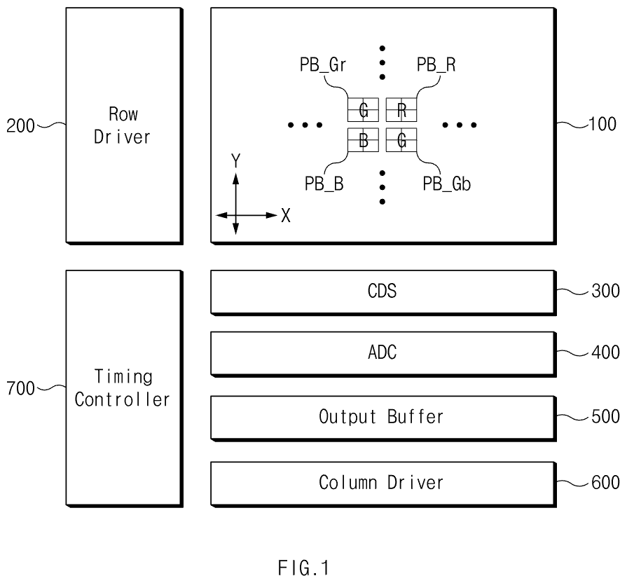

FIG. 1 is a block diagram illustrating an example of an image sensing device based on an embodiment of the disclosed technology.

Referring to FIG. 1, the image sensing device may include a pixel array 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 100 may include a plurality of pixel blocks (PB_R, PB_Gr, PB_Gb, PB_B) consecutively arranged in a two-dimensional (2D) matrix (including an X-axis direction and a Y-axis direction perpendicular to the X-axis direction). The pixel blocks (PB_R, PB_Gr, PB_Gb, PB_B) may be arranged in a Bayer pattern. Each of the pixel blocks (PB_R, PB_GR, PB_GB, PB_B) may include a structure in which a plurality of unit pixels shares one floating diffusion region. Each unit pixel may include a photoelectric conversion region (e.g., a photodiode PD) that generates photocharges through photoelectric conversion of incident light, and a plurality of transfer gates that transmits the photocharges generated by the photoelectric conversion region to a common floating diffusion region in response to a transfer signal. Adjacent unit pixels may be isolated by a trench-type pixel isolation structure, and the transfer gates may include recess gates embedded in the pixel isolation structure. The pixel array 100 may also be formed in a structure in which the unit pixels are arranged in a Bayer pattern.

The row driver 200 may operate the unit pixels based on control signals received from a control circuit such as a timing controller 700.

The correlated double sampler (CDS) 300 may remove undesired offset values of the unit pixels using correlated double sampling.

The ADC 400 may convert the CDS signal received from the correlated double sampler (CDS) 300 into a digital signal.

The output buffer 500 may temporarily store column-based data received from the ADC 400 under the control of the timing controller 700.

The column driver 600 may select a column of the output buffer 500 under the control of the timing controller 700, and may sequentially output data temporarily stored in the selected column of the output buffer 500.

The timing controller 700 may generate signals for controlling the row driver 200, the ADC 400, the output buffer 500 and the column driver 600.

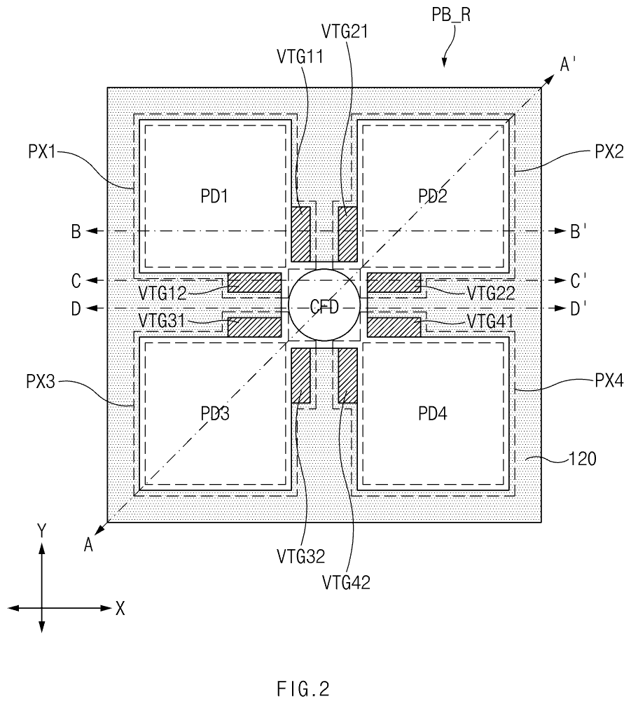

FIG. 2 is a plan view illustrating an example of a planar structure of one pixel block in the pixel array 100 shown in FIG. 1 based on an embodiment of the disclosed technology.

Since the pixel blocks (PB_R, PB_Gr, PB_Gb, PB_B) have the same structure except for the color of the color filter, the present embodiment will describe only the pixel block (PB_R) as a representative example.

Referring to FIG. 2, the pixel block (PB_R) may include four unit pixels (PX1-PX4) adjacently arranged in a (2×2) matrix structure. The unit pixels (PX1-PX4) may be isolated from each other by a pixel isolation structure 120. The pixel isolation structure 120 may include a deep trench isolation (DTI) structure in which an insulation material and a conductive material are formed within a trench formed by etching a substrate, e.g., a semiconductor substrate.

Each of the unit pixels (PX1-PX4) may include one photoelectric conversion region (PD) and two transfer gates (VTG). For example, the unit pixel (PX1) may include a photoelectric conversion region (PD1) and transfer gates (VTG11, VTG12) disposed at two sides of the photoelectric conversion region (PD1). The transfer gates (VTG11, VTG12) may be arranged adjacent to two sides of the photoelectric conversion region (PD1). The unit pixel (PX2) may include a photoelectric conversion region (PD2) and transfer gates (VTG21, VTG22) arranged adjacent to two sides of the photoelectric conversion region (PD2). The unit pixel (PX3) may include a photoelectric conversion region (PD3) and transfer gates (VTG31, VTG32) arranged adjacent to two sides of the photoelectric conversion region (PD3). The unit pixel (PX4) may include a photoelectric conversion region (PD4) and transfer gates (VTG41, VTG42) arranged adjacent to two sides of the photoelectric conversion region (PD4). In some implementations, the term “transfer gate” refers to a component that transmits the photocharges generated by a photoelectric conversion region to a floating diffusion region.

The photoelectric conversion regions (PD1-PD4) may generate photocharges through photoelectric conversion of incident light, and may accumulate the photocharges therein. The transfer gates (VTG11-VTG42) may transfer photocharges accumulated in the corresponding photoelectric conversion regions (PD1-PD4) to a floating diffusion region (CFD) based on a transfer control signal. In some implementations, the term “floating diffusion region (CFD)” refers to a region that acts as a temporary storage area for the photocharges generated by the photoelectric conversion regions (PD1-PD4).

The transfer gates (VTG11-VTG42) may be embedded in the pixel isolation structure 120, located adjacent to two sides of the corresponding photoelectric conversion regions (PD1-PD4) between the floating diffusion region (CFD) and the photoelectric conversion regions (PD1-PD4) without overlapping the photoelectric conversion regions (PD1-PD4). For example, the transfer gates (VTG11-VTG42) may be disposed on two adjoining side surfaces (e.g., side surfaces that meet each other) of the photoelectric conversion regions (PD1-PD4), and may be designed to avoid vertical overlap with the photoelectric conversion regions (PD1-PD4). Each of the transfer gates (VTG11-VTG42) may be formed in a recess gate shape embedded in the pixel isolation structure 120. In this case, the vertical direction may refer to a depth direction of the semiconductor substrate, perpendicular to the first direction and the second direction.

The unit pixels (PX1-PX4) may share one floating diffusion region (CFD). For example, only one floating diffusion region (CFD) may be located between the photoelectric conversion regions (PD1-PD4) of the unit pixels (PX1-PX4), and the photoelectric conversion regions (PD1-PD4) may be commonly connected to the floating diffusion region (CFD) through a channel region of the semiconductor substrate.

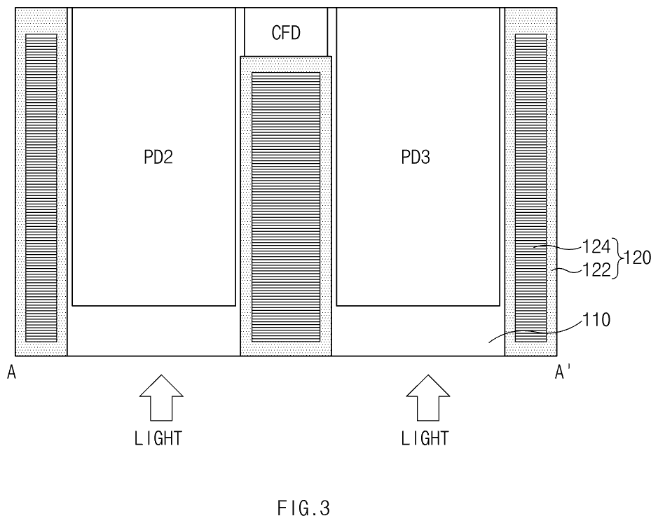

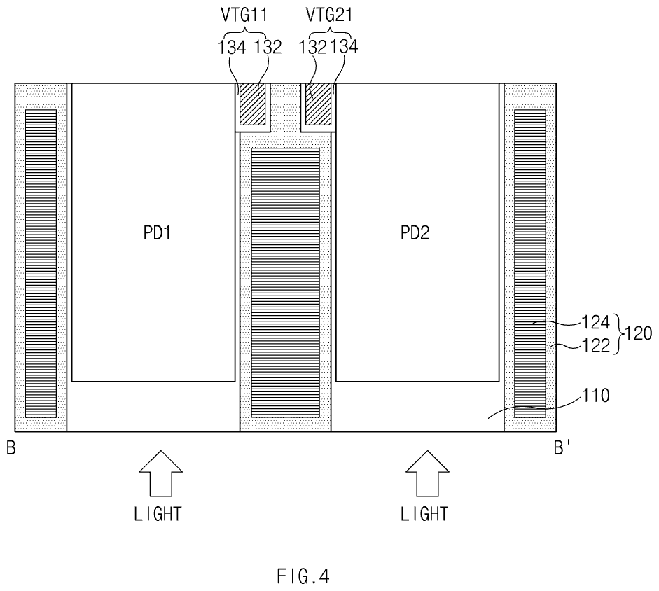

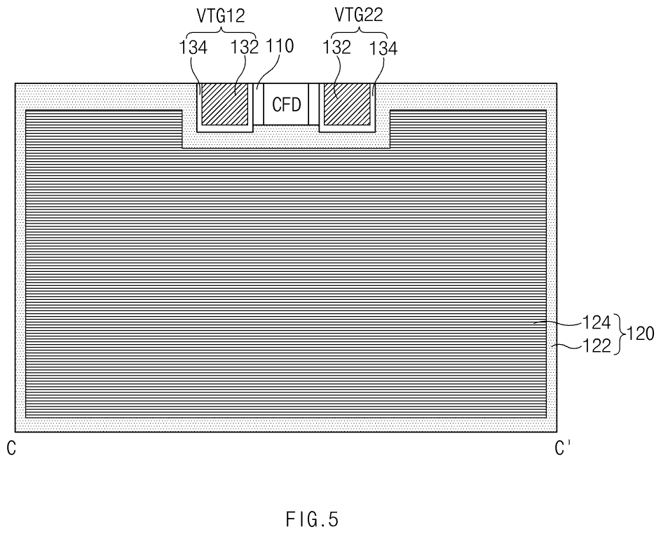

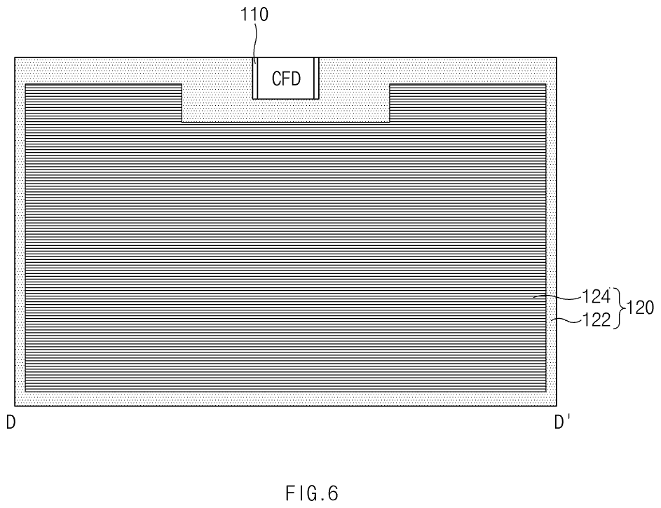

FIG. 3 is a cross-sectional view illustrating a cross-section of the pixel block taken along the line A-A′ shown in FIG. 2. FIG. 4 is a cross-sectional view illustrating a cross-section of the pixel block taken along the line B-B′ shown in FIG. 2. FIG. 5 is a cross-sectional view illustrating a cross-section of the pixel block taken along the line C-C′ shown in FIG. 2. FIG. 6 is a cross-sectional view illustrating a cross-section of the pixel block taken along the line D-D′ shown in FIG. 2.

Referring to FIGS. 3 to 6, a substrate 110 (e.g., a semiconductor substrate) may include a first surface and a second surface facing or opposite to the first surface, and may be isolated for each unit pixel (PX) by a pixel isolation structure 120. In some implementations, the first surface may be a surface upon which light is incident. The semiconductor substrate 110 may be in a monocrystalline state, and may include a silicon-containing material. The semiconductor substrate 110 may include P-type impurities implanted by ion implantation.

Referring to FIGS. 3 and 4, the pixel isolation structure 120 may be disposed between adjacent photoelectric conversion regions (PD1-PD4) within the semiconductor substrate 110 to separate the photoelectric conversion regions (PD1-PD4) from each other. The pixel isolation structure 120 may include a DTI structure in which an insulation material and a conductive material are buried in a trench formed by etching the semiconductor substrate 110, and some regions of the pixel isolation structure 120 may be formed to penetrate the semiconductor substrate 110. The pixel isolation structure 120 may include a DTI insulation layer 122 and a DTI electrode 124.

The DTI insulation layer 122 may be formed to partially penetrate the semiconductor substrate 110. For example, as shown in FIGS. 3 to 6, the DTI insulation layer 122 may be formed to penetrate the substrate 110 in a region surrounding the photoelectric conversion regions (PD1-PD4). As shown in FIGS. 3, 5, and 6, the DTI insulation layer 122 may be formed such that the DTI insulation layer 122 does not penetrate the substrate 110 in a region in which the floating diffusion region (CFD) is formed.

The DTI insulation layer 122 may be formed not only between the substrate 110 and the DTI electrode 124 but also at upper and lower portions of the DTI electrode 124, as shown in FIGS. 3 and 4. For example, the DTI insulation layer 122 may be formed to surround the DTI electrode 124. The DTI insulation layer 122 may include an oxide layer.

The DTI electrode 124 may be formed within the DTI insulation layer 122, and may be formed in a barrier shape surrounding the photoelectric conversion regions (PD1-PD4). The DTI electrode 124 may be formed of a conductive material that includes at least one of metal, polysilicon, or doped polysilicon doped with impurities, without being limited thereto.

In some implementations, a height of the DTI electrode varies depending on where the DTI electrode is formed. As shown in FIGS. 3 to 6, the DTI electrode 124 may have different heights that vary depending on where the corresponding portion of the DTI electrode 124 is formed. For example, the DTI electrode 124 may be formed such that the height of the DTI electrode 124 within a specific region in which the floating diffusion region (CFD) and the transfer gates (VTG11-VTG42) are formed is different from the height of the DTI electrode 124 within in the remaining regions other than the specific region. Since the DTI electrode 124 should be spaced apart from the floating diffusion region (CFD) and the transfer gates (VTG11-VTG42) by a predetermined distance or greater so that electrical interference with the floating diffusion region (CFD) and the transfer gates (VTG11-VTG42) does not occur, the height of the DTI electrode 124 within the region where the floating diffusion region (CFD) and the transfer gates (VTG11-VTG42) are formed may be lower than the height of the DTI electrode 124 within the remaining regions. In some implementations, the region where the floating diffusion region (CFD) and the transfer gates (VTG11-VTG42) are formed may refer to a region that vertically overlaps the floating diffusion region (CFD) and the transfer gates (VTG11-VTG42) and another region adjacent to the region.

The DTI electrode 124 may be formed such that regions extending in the first direction and other regions extending in the second direction cross each other, forming a connected structure as a whole. The DTI electrode 124 may receive a bias voltage (Vb) as an input. For example, the DTI electrode 124 may be formed to extend to a peripheral region of the pixel array 100, and may receive a negative bias voltage (Vb) through a contact (e.g., a structure that connects a component to another component or an interconnect in a semiconductor device) and conductive line (e.g., interconnect) formed on the second surface of the substrate 110 in the peripheral region.

In an embodiment, when the pixel isolation structure is formed in a trench shape by etching the semiconductor substrate, dangling bonds may be formed at the interface of the trench. These dangling bonds may generate surplus charges (electrons), which act as a dark current source. Such surplus charges may deteriorate the operational characteristics of the image sensing device. In an embodiment, to mitigate dark current effects, the DTI electrode 124 including a conductive material may be formed within the pixel isolation structure 120, and a negative bias voltage may be applied to the DTI electrode 124.

As shown in FIGS. 3 and 4, photoelectric conversion regions (PD1-PD4) may be formed in the region defined by the pixel isolation structure 120 within the semiconductor substrate 110.

The photoelectric conversion regions (PD1-PD4) may include N-type impurities, and may convert incident light into photocharges. The photoelectric conversion regions (PD1-PD4) may be formed such that each unit pixel (PX1-PX4) includes a photoelectric conversion region, and adjacent photoelectric conversion regions may be isolated from each other by the pixel isolation structure 120.

As shown in FIGS. 3 and 4, the photoelectric conversion regions (PD1-PD4) may be disposed within the semiconductor substrate 110, such that the top surfaces of the photoelectric conversion regions (PD1-PD4) contact the second surface of the semiconductor substrate 110 and the bottom surfaces of the photoelectric conversion regions (PD1-PD4) are spaced apart from the first surface of the semiconductor substrate 110 by a predetermined distance. In an embodiment, since the transfer gates (VTG11-VTG42) are not formed on the photoelectric conversion regions (PD1-PD4), the photoelectric conversion regions (PD1-PD4) may extend to the second surface of the semiconductor substrate 110. As a result, the overall volume of the photoelectric conversion region (PD1-PD4) for each unit pixel can increase, thereby increasing the well capacity or reducing the size of each unit pixel. In addition, since the photoelectric conversion regions (PD1-PD4) extend to the second surface of the semiconductor substrate 110, the distance between the floating diffusion region (CFD) and the photoelectric conversion regions (PD1-PD4) can be shortened, thereby enhancing the transmission efficiency of photocharges.

The floating diffusion region (CFD) may temporarily store photocharges received from the photoelectric conversion regions (PD1-PD4). As shown in FIGS. 3, 5, and 6, the floating diffusion region (CFD) may be formed in the semiconductor substrate 110, extending to a predetermined depth from the second surface of the semiconductor substrate 110 while being in contact with the second surface of the semiconductor substrate 110. As shown in FIG. 3, the floating diffusion region (CFD) may not overlap the photoelectric conversion regions (PD1-PD4) in the vertical direction, and may be disposed at one side of the photoelectric conversion regions (PD1-PD4) in the horizontal direction. The floating diffusion region (CFD) may be disposed in a crossing region of the pixel isolation structure 120 in a space between the photoelectric conversion regions (PD1-PD4). For example, the floating diffusion region (CFD) may be formed to vertically overlap with the crossing region where a first extension region in which the pixel isolation structure 120 is extended in the first direction and a second extension region in which the pixel isolation structure 120 is extended in the second direction are intersected.

As shown in FIGS. 3, 5, and 6, the bottom surface of the floating diffusion region (CFD) may be spaced apart from the DTI electrode 124 of the pixel isolation structure 120 by a predetermined distance. The floating diffusion region (CFD) may include N-type impurities.

As shown in FIG. 3, the photoelectric conversion regions (PD1-PD4) and the floating diffusion region (CFD) may be connected to each other through a channel region in the semiconductor substrate 110. For example, when each of the transfer gates (VTG11-VTG42) receives a transfer control signal from the row driver 200, a channel may be formed in the semiconductor substrate 110 between the floating diffusion region (CFD) and the photoelectric conversion regions (PD1-PD4), allowing the photoelectric conversion regions (PD1-PD4) to be selectively connected to the floating diffusion region (CFD).

The transfer gates (VTG11-VTG42) may form a channel in the semiconductor substrate 110 between the floating diffusion region (CFD) and the photoelectric conversion regions (PD1-PD4) based on a transfer control signal, and may transmit photocharges generated by the photoelectric conversion regions (VTG11-VTG42) to the floating diffusion region (CFD). The transfer gates (VTG11-VTG42) may be disposed at side portions of the photoelectric conversion regions (PD1-PD4) to avoid vertical overlap with the photoelectric conversion regions (PD1-PD4), and may be embedded in the DTI insulation layer 122 of the pixel isolation structure 120.

As shown in FIGS. 4 and 5, the transfer gates (VTG11-VTG42) may include a gate electrode 132 and a gate insulation layer 134.

The gate electrode 132 may include a conductive material. For example, the gate electrode 132 may include at least one of metal, polysilicon, or doped polysilicon doped with impurities. The gate electrode 132 may include the same material as the DTI electrode 124. The gate electrode 132 and the DTI electrode 124 may be sufficiently spaced apart from each other to reduce or prevent any interference between the gate electrode 132 and the DTI electrode 124.

The gate insulation layer 134 may be formed to surround the side surfaces and the bottom surface of the gate electrode 132. The gate insulation layer 134 may include the same material as the DTI insulation layer 122.

Each of the transfer gates (VTG11-VTG42) may be designed to have a preset size suitable for the transmission of photocharges. For example, the gate electrode 132 of each of the transfer gates (VTG11-VTG42) may extend to a depth equal to the depth of the bottom surface of the floating diffusion region (CFD) in the vertical direction, or may extend to a depth greater than the depth of the bottom surface of the floating diffusion region (CFD).

In addition, the transfer gates (VTG12, VTG22, VTG31, VTG41) may be formed to extend in the first direction (e.g., X-axis direction) by a length equal to the length of each of the photoelectric conversion region (PD1-PD4), and the transfer gates (VTG11, VTG21, VTG32, VTG42) may be formed to extend in the second direction (e.g., Y-axis direction) by a length equal to the length of each of photoelectric conversion region (PD1-PD4).

In the above-described example, the pixel array 100 includes the pixel blocks (PB_R, PB_Gr, PB_Gb, PB_B) arranged in the Bayer pattern. However, the pixel array may include a plurality of unit pixels arranged in the Bayer pattern.

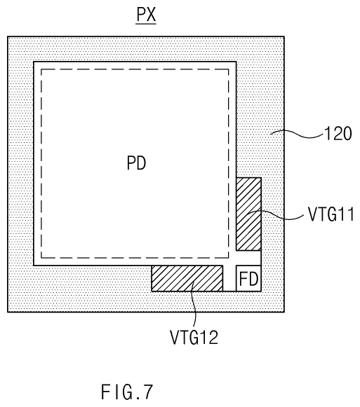

FIG. 7 is a plan view illustrating an example of a planar structure of each unit pixel (PX) when the pixel array 100 of FIG. 1 includes the plurality of unit pixels arranged in the Bayer pattern based on an embodiment of the disclosed technology.

In an embodiment, the pixel array 100 of FIG. 1 may include a plurality of unit pixels (PX) consecutively arranged in the first direction and the second direction perpendicular to the first direction, and the unit pixels (PX) may be arranged in the Bayer pattern.

The unit pixels (PX) in FIG. 7 are different from the unit pixels (PX1-PX4) in FIG. 2 in that a floating diffusion region (FD) is independently formed for each unit pixel (PX). As shown in FIG. 7, even in a structure in which the floating diffusion region (FD) is formed for each unit pixel (PX), the transfer gates (VTG11, VTG12) may be formed at the side of the photoelectric conversion region (PD), embedded in the DTI insulation layer 122 of the pixel isolation structure 120, without overlapping the photoelectric conversion region (PD) in the vertical direction.

In an embodiment, as shown in FIGS. 3 to 6 described above, the pixel isolation structure 120 may include a DTI electrode and a DTI insulation layer, and each of the transfer gates (VTG11, VTG12) may include a gate electrode and a gate insulation layer. The pixel isolation structure 120 and the transfer gates (VTG11, VTG12) of FIG. 7 may be formed in the same manner as illustrated in FIGS. 3 to 6, and thus a detailed description thereof is omitted here for brevity.

As is apparent from the above description, the image sensing device based on some embodiments of the disclosed technology may improve its operational characteristics.

The image sensing device based on the embodiments of the disclosed technology may enhance the transmission characteristics of photocharges while increasing its well capacity.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a substrate including a first surface and a second surface facing or opposite to the first surface;
a plurality of photoelectric conversion regions arranged adjacent to each other within the substrate and configured to convert incident light received through the first surface into photocharges;
a pixel isolation structure disposed between adjacent photoelectric conversion regions of the plurality of photoelectric conversion regions within the substrate to isolate the adjacent photoelectric conversion regions from each other;
a floating diffusion region disposed between the plurality of photoelectric conversion regions and in contact with the second surface of the substrate; and
a plurality of transfer gates disposed on side surfaces of the plurality of photoelectric conversion regions so as not to vertically overlap the plurality of photoelectric conversion regions.

2. The image sensing device according to claim 1, wherein:
the photoelectric conversion regions are spaced apart from the first surface of the substrate, and are in contact with the second surface of the substrate.

3. The image sensing device according to claim 1, wherein:
the floating diffusion region is disposed such that the floating diffusion region does not vertically overlap the plurality of photoelectric conversion regions.

4. The image sensing device according to claim 1, wherein:
the floating diffusion region is disposed to vertically overlap the pixel isolation structure.

5. The image sensing device according to claim 4, wherein:
the floating diffusion region is disposed at a region where a first area extending in a first direction in the pixel isolation structure and a second area extending in a second direction perpendicular to the first direction in the pixel isolation structure cross each other.

6. The image sensing device according to claim 1, wherein:
a portion of the pixel isolation structure penetrates the substrate.

7. The image sensing device according to claim 6, wherein:
the pixel isolation structure does not penetrate the substrate in a region where the pixel isolation structure and the floating diffusion region vertically overlap each other; and the pixel isolation structure penetrates the substrate in remaining regions other than the region.

8. The image sensing device according to claim 1, wherein the pixel isolation structure includes:
a deep trench isolation (DTI) insulation layer; and
a DTI electrode buried in the DTI insulation layer.

9. The image sensing device according to claim 8, wherein:
a height of the DTI electrode varies depending on where the DTI electrode is formed.

10. The image sensing device according to claim 9, wherein:
a height of the DTI electrode within a region where the floating diffusion region and the plurality of transfer gates are formed is lower than a height of the DTI electrode within remaining regions other than the region.

11. The image sensing device according to claim 1, wherein each of the plurality of transfer gates includes:
a gate electrode; and
a gate insulation layer formed to surround the gate electrode.

12. The image sensing device according to claim 11, wherein:
the gate electrode vertically extends to: a bottom surface of the floating diffusion region; or a depth greater than a depth of the bottom surface of the floating diffusion region.

13. The image sensing device according to claim 1, wherein:
each of the plurality of transfer gates extends in a first direction or in a second direction intersecting the first direction, by a length corresponding to each of the photoelectric conversion regions.

14. The image sensing device according to claim 1, wherein:
the plurality of transfer gates is arranged adjacent to two adjoining side surfaces of each photoelectric conversion region.

15. An image sensing device comprising:
a substrate including a first surface and a second surface facing or opposite to the first surface;
a photoelectric conversion region disposed in the substrate and in contact with the second surface of the substrate, and configured to generate photocharges by converting incident light received through the first surface of the substrate;
a floating diffusion region spaced apart from the photoelectric conversion region and in contact with the second surface of the substrate; and
a plurality of transfer gates disposed on side surfaces of the photoelectric conversion region so as not to vertically overlap the photoelectric conversion region.

16. The image sensing device according to claim 15, wherein:
the plurality of transfer gates is arranged adjacent to two adjoining side surfaces of the photoelectric conversion region.

17. The image sensing device according to claim 15, wherein each of the plurality of transfer gates includes:
a gate electrode; and
a gate insulation layer formed to surround the gate electrode.

18. The image sensing device according to claim 17, wherein:
the gate electrode vertically extends to: a depth equal to a depth of a bottom surface of the floating diffusion region; or a depth greater than the depth of the bottom surface of the floating diffusion region.

19. The image sensing device according to claim 15, wherein:
each of the plurality of transfer gates extends in a first direction or in a second direction intersecting the first direction, by a length corresponding to the photoelectric conversion region.
